(19) United States
(12) Patent Application Publication
(10) Pub. No.: US 2026/0150234 A1
(43) Pub. Date: May 28, 2026

(54) RADIATOR AND TERMINAL DEVICE

(71) Applicants: CHAMP TECH OPTICAL (FOSHAN) CORPORATION, Foshan (CN); Foxconn Technology Co., Ltd., New Taipei (TW)

(72) Inventors: Meng Fu, Foshan (CN); Jin-Rong Xie, Foshan (CN); Fu-Sheng Luo, Foshan (CN)

(21) Appl. No.: 19/066,508

(22) Filed: Feb. 28, 2025

(30) Foreign Application Priority Data
Nov. 27, 2024 (CN) 202411719273.1

(51) Int. Cl. H05K 7/20

(52) U.S. Cl. CPC H05K 7/20263

(57) ABSTRACT

A radiator includes a first heat dissipating assembly, a second heat dissipating assembly, an inlet connector, and an outlet connector. The first heat dissipating assembly includes a first channel, a first inlet hole, and a first outlet hole. The first channel is connected to the first inlet hole and the first outlet hole. The second heat dissipating assembly is detachably connected to the first heat dissipating assembly. The second heat dissipating assembly includes a second channel, a second inlet hole, and a second outlet hole. The second channel communicates with the second inlet hole and the second outlet hole. The second inlet hole communicates with the first inlet hole. The second outlet hole communicates with the first outlet hole. The inlet connector communicates with the first inlet hole. The outlet connector communicates with the first outlet hole. The present disclosure further provides a terminal device.

### FIELD

The subject matter herein generally relates to heat dissipation, and more particularly, to a radiator and a terminal device.

### BACKGROUND

A terminal device, such as a server, may include a number of memory modules and a radiator for dissipating heat from the memory modules. The structure of the radiator is generally fixed, which means that the radiator may dissipate heat from a fixed number of memory modules and cannot be adapted according to different usage scenarios. In addition, the heat dissipation efficiency of the radiator is generally low. Therefore, there is a room for improvement in the art.

### BRIEF DESCRIPTION OF THE DRAWINGS

Implementations of the present technology will now be described, by way of example only, with reference to the attached figures.

FIG. 1 is a diagrammatic view illustrating a terminal device according to an embodiment of the present disclosure.

FIG. 2 is a diagrammatic view of a radiator of FIG. 1.

FIG. 3 is a cross-sectional view of the radiator along a view line A-A of FIG. 2.

FIG. 4 is a cross-sectional view of the radiator along a view line B-B of FIG. 2.

FIG. 5 is a diagrammatic view showing a working fluid flowing in the radiator of FIG. 2.

FIG. 6 is an exploded view of the radiator of FIG. 2.

FIG. 7 is similar to FIG. 6, but showing the radiator viewed from another angle.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

Some embodiments of the present disclosure will be described in detail with reference to the drawings. If no conflict, the following embodiments and features in the embodiments can be combined with each other.

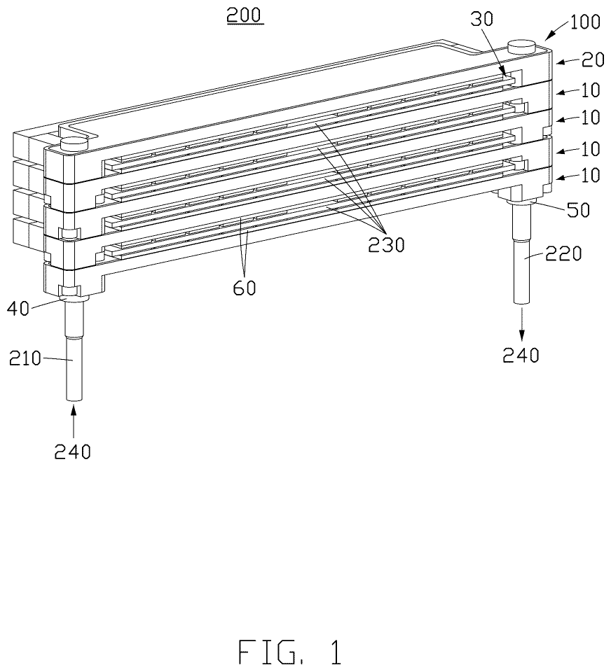

FIG. 1 is a diagrammatic view illustrating a terminal device 200 according to an embodiment of the present disclosure. The terminal device 200 can include a radiator 100, an inlet tube 210, an outlet tube 220, and at least one working member 230. The working member 230 is connected to the radiator 100. The inlet tube 210 and the outlet tube 220 communicate with the radiator 100.

The working member 230 generates heat during operation. The working fluid 240 is injected into the radiator 100 through the inlet tube 210, that is, the working fluid 240 enters the radiator 100 from the inlet tube 210. The working fluid 240 further flows through the radiator 100 and is discharged through the outlet tube 220. As the working fluid 240 flows, the working fluid 240 dissipates the heat generated by the working member 230, thereby maintaining the working environment of the working member 230 within a suitable temperature range.

The working member 230 can be a memory module, a chip, etc. The working fluid 240 can be water.

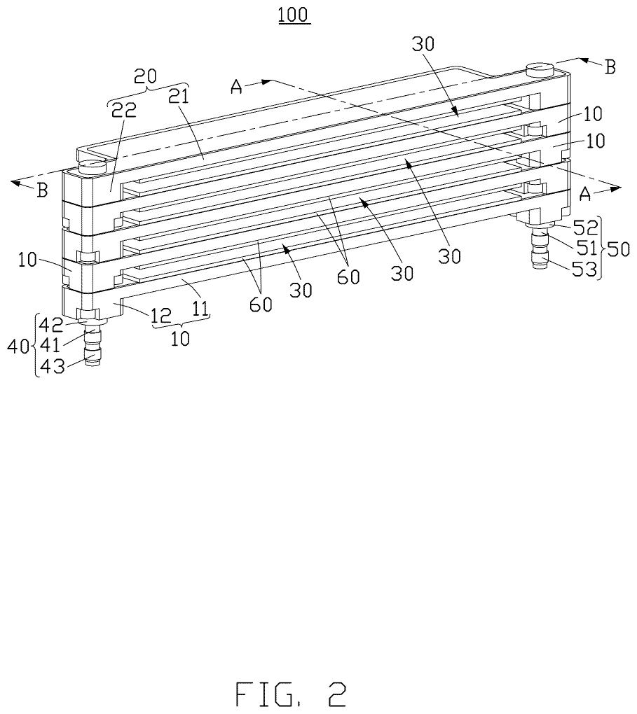

Referring to FIG. 2, the radiator 100 can include at least one first heat dissipating assembly 10, a second heat dissipating assembly 20, an inlet connector 40, and an outlet connector 50. The number of first heat dissipating assembly 10 can be one or more, and can be increased or decreased as needed. In the embodiment, the radiator 100 includes four first heat dissipating assemblies 10. The four first heat dissipating assemblies 10 are stacked with each other, and the second heat dissipating assembly 20 is located on an outermost one of the four first heat dissipating assemblies 10. The inlet connector 40 and the outlet connector 50 communicate with another outermost one of the four first heat dissipating assemblies 10. The inlet connector 40 communicates with the inlet tube 210, and the outlet connector 50 communicates with the outlet tube 220.

Each first heat dissipating assembly 10 includes a first body portion 11 and a first mounting portion 12. The first body portion 11 is fixed to the first mounting portion 12. The first mounting portion 12 is located on a side of the first body portion 11 facing away from the second heat dissipating assembly 20. The second heat dissipating assembly 20 includes a second body portion 21 and a second mounting portion 22. The second mounting portion 22 is disposed between the first body portion 11 and the second body portion 21. An installing space 30 is formed between the first body portion 11 and the second body portion 21. When the radiator 100 includes a plurality of first heat dissipating assemblies 10, the installing space 30 is further formed between the first body portions 11 of two adjacent first heat dissipating assemblies 10. There are a plurality of working members 230, and each working member 230 is disposed in one installing space 30. The working member 230 is connected to the first body portion 11 and/or the second body portion 21, thereby facilitating the transfer of heat to the first heat dissipating assembly 10 and/or the second heat dissipating assembly 20.

In some embodiments, the radiator 100 can further include a plurality of heat conducting sheets 60. Two of the heat conducting sheets 60 are disposed in each installing space 30 and on the surfaces of the first heat dissipating assemblies 10 and the second heat dissipating assembly 20. That is, the heat conducting sheets 60 are disposed on opposite surfaces of the corresponding working member 230. The heat conducting sheets 60 can connect the first heat dissipating assemblies 10 to the working member 230 or connect the second heat dissipating assembly 20 to the working member 230. The heat conducting sheets 60 can transfer the heat generated by the working member 230 to the first heat dissipating assembly 10 and the second heat dissipating assembly 20, thereby allowing the radiator 100 to quickly dissipate the heat.

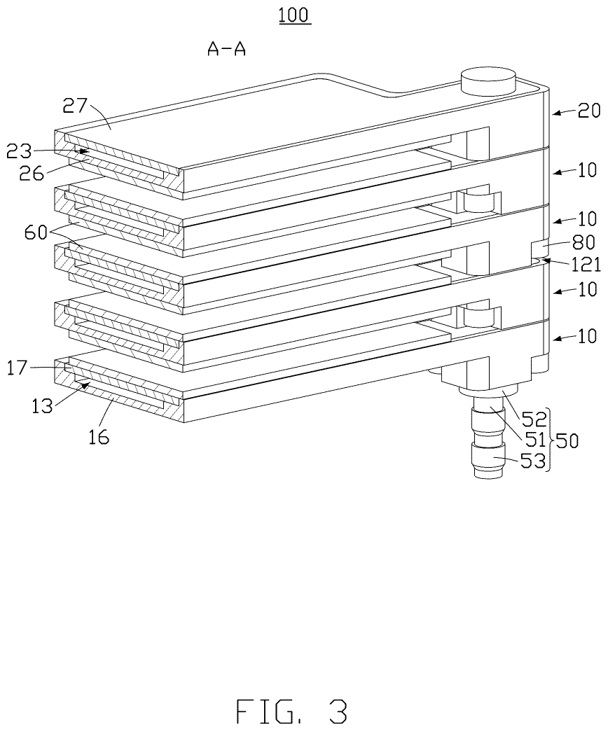

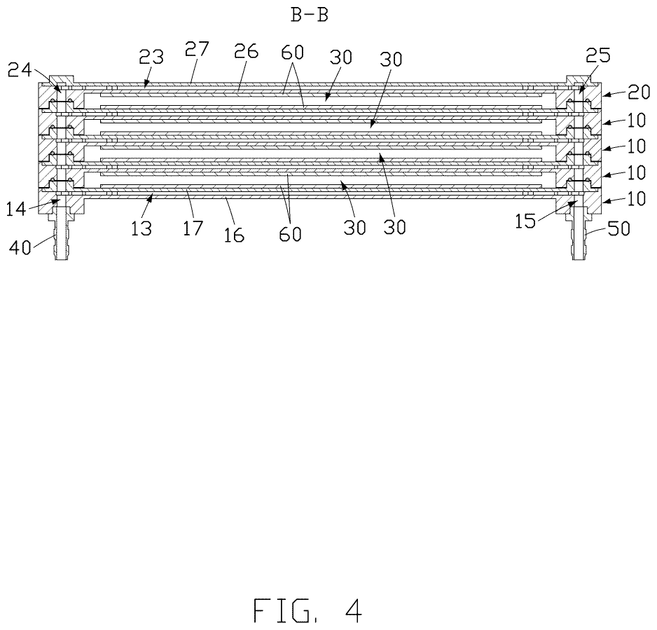

Referring to FIGS. 3 and 4, FIG. 3 is a cross-sectional view of the radiator 100 along a view line A-A of FIG. 2, and FIG. 4 is a cross-sectional view of the radiator 100 along a view line B-B of FIG. 2. Each first heat dissipating assembly 10 can include a first channel 13, a first inlet hole 14, and a first outlet hole 15. The first channel 13 communicates with the first inlet hole 14 and the first outlet hole 15. Each of the first inlet hole 14 and the first outlet hole 15 extends through the first heat dissipating assembly 10.

The first heat dissipating assembly 10 further includes a first heat dissipating plate 16 and a first covering plate 17. The first heat dissipating plate 16 is fixed to the first covering plate 17. The first heat dissipating plate 16 and the first covering plate 17 cooperatively define the first channel 13. The first inlet hole 14 extends through the first heat dissipating plate 16 and the first covering plate 17. The first outlet hole 15 also extends through the first heat dissipating plate 16 and the first covering plate 17. The first channel 13 communicates with the first inlet hole 14 and the first outlet hole 15. The first body portion 11 includes the portions of the first heat dissipating plate 16 and the first covering plate 17 forming the first channel 13. The heat conducting sheets 60 are disposed on the surfaces of the first heat dissipating plate 16 and the first covering plate 17.

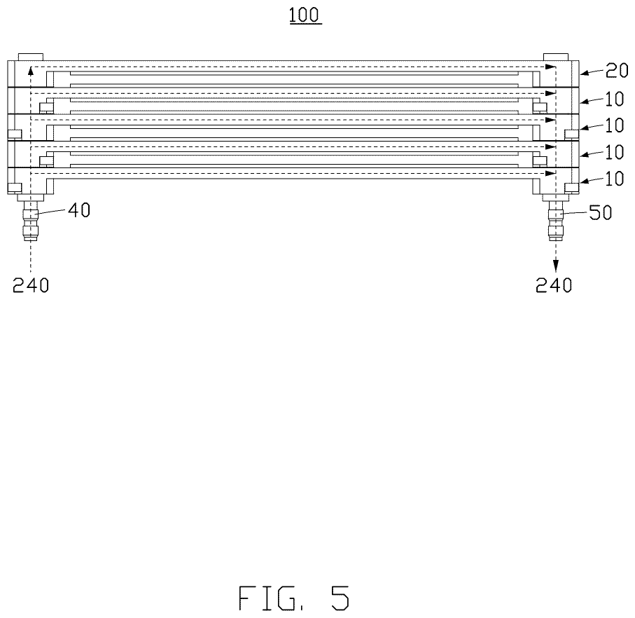

Referring to FIG. 5, the working fluid 240 enters the inlet tube 210 and flows through the first inlet hole 14, the first channel 13, and the first outlet hole 15, and finally exits through the outlet tube 220. When the working fluid 240 flows through the first channel 13, the working fluid 240 absorbs the heat that the heat conducting sheets 60 transfer to the first heat dissipating plate 16 and the first covering plate 17, thereby achieving the effect of heat dissipating.

The second heat dissipating assembly 20 can include a second channel 23, a second inlet hole 24, and a second outlet hole 25. The second channel 23 communicates with the second inlet hole 24 and the second outlet hole 25, the second inlet hole 24 communicates with the first inlet hole 14, and the second outlet hole 25 communicates with the first outlet hole 15.

The second heat dissipating assembly 20 can further include a second heat dissipating plate 26 and a second covering plate 27. The second heat dissipating plate 26 and the second covering plate 27 cooperatively define the second channel 23. The second inlet hole 24 extends through the second heat dissipating plate 26 and communicates with the first inlet hole 14. The second outlet hole 25 extends through the second heat dissipating plate 26 and communicates with the first outlet hole 15. The second body portion 21 includes the portions of the second heat dissipating plate 26 and the second covering plate 27 forming the second channel 23. The heat conducting sheets 60 are disposed on the surface of the second heat dissipating plate 26.

The working fluid 240 enters the inlet tube 210 and flows through the first inlet hole 14, the second inlet hole 24, the second channel 23, the second outlet hole 25, and the first outlet hole 15, and finally exits through the outlet tube 220. When the working fluid 240 flows through the second channel 23, the working fluid 240 absorbs the heat that the heat conducting sheets 60 transfer to the second heat dissipating plate 26, thereby achieving the heat dissipating effect.

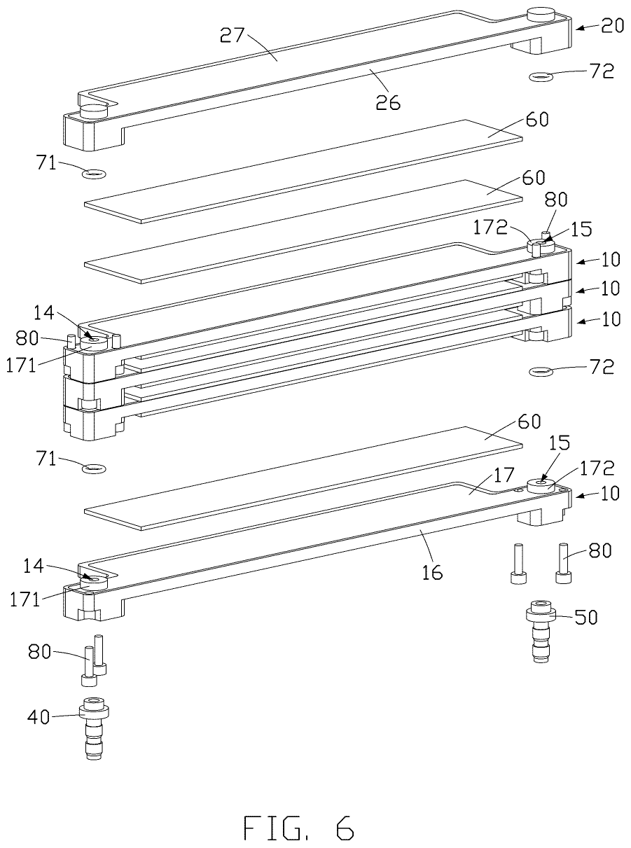

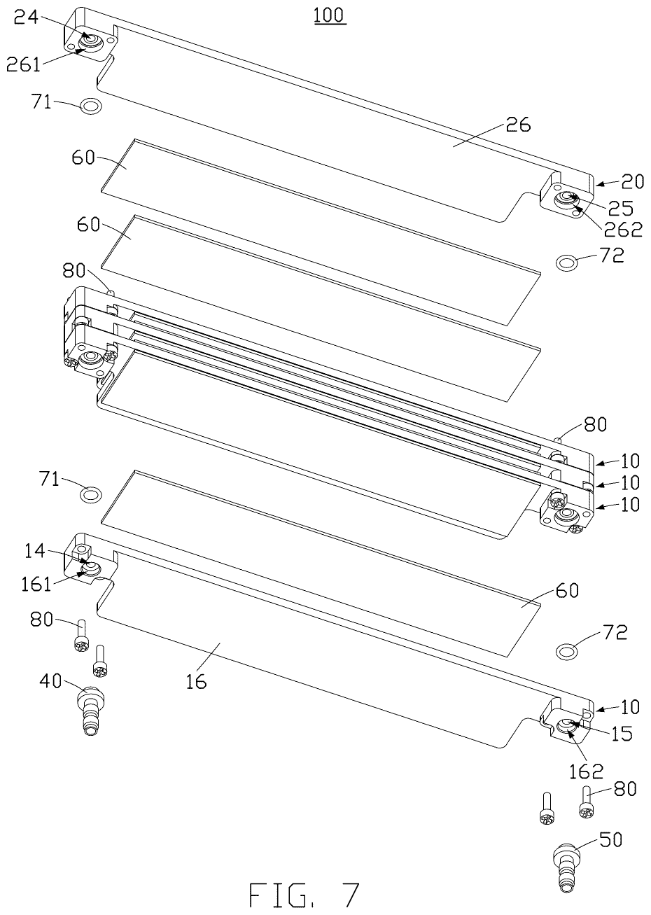

Referring to FIGS. 6 and 7, FIG. 6 is an exploded view of the radiator 100 of FIG. 2, FIG. 7 is similar to FIG. 6, but showing the radiator 100 viewed from another angle. A first accommodating groove 161 and a second accommodating groove 162 are defined on each first heat dissipating plate 16. The first accommodating groove 161 communicates with the first inlet hole 14, and the second accommodating groove 162 communicates with the first outlet hole 15. The inlet connector 40 includes a first connecting portion 41 and a first protrusion 42. The first protrusion 42 surrounds the first connecting portion 41. A portion of the first connecting portion 41 is received in the first accommodating groove 161 of one of the first heat dissipating assemblies 10. The first protrusion 42 abuts against the first heat dissipating assembly 10. The outlet connector 50 includes a second connecting portion 51 and a second protrusion 52. The second protrusion 52 surrounds the second connecting portion 51. A portion of the second connecting portion 51 is received in the second accommodating groove 162 of one of the first heat dissipating assemblies 10. The second protrusion 52 abuts against the first heat dissipating assembly 10. The inlet connector 40 and the outlet connector 50 are connected to the same first heat dissipating assembly 10.

The inlet connector 40 further includes at least one third protrusion 43. The third protrusion 43 surrounds the first connecting portion 41 and is located on a side of the first protrusion 42 opposite to the first heat dissipating assembly 10. In the embodiment, the inlet connector 40 includes two third protrusions 43. The inlet tube 210 is sleeved onto the side of the first connecting portion 41 opposite to the first heat dissipating assembly 10. The third protrusions 43 can increase the diameter of the inlet tube 210, thereby facilitating a tight connection between the inlet tube 210 and the inlet connector 40.

The outlet connector 50 further includes at least one fourth protrusion 53. The fourth protrusion 53 surrounds the second connecting portion 51 and is located on the side of the second protrusion 52 opposite to the first heat dissipating assembly 10. In the embodiment, the outlet connector 50 includes two fourth protrusions 53. The outlet tube 220 is sleeved onto the side of the second connecting portion 51 opposite to the first heat dissipating assembly 10. The fourth protrusions 53 can increase the diameter of the outlet tube 220, thereby facilitating a tight connection between the outlet tube 220 and the outlet connector 50.

The first heat dissipating assembly 10 further includes a first protruding portion 171 and a second protruding portion 172. The first inlet hole 14 extends through the first protruding portion 171. The first outlet hole 15 extends through the second protruding portion 172. The second heat dissipating assembly 20 further includes a first groove 261 and a second groove 262. The second inlet hole 24 communicates with the first groove 261. The second outlet hole 25 communicates with the second groove 262. The first protruding portion 171 is received in the first groove 261, and the second protruding portion 172 is received in the second groove 262, thereby facilitating the assembly of the inlet connector 40 with the first heat dissipating assembly 10 and the assembly of the outlet connector 50 with the first heat dissipating assembly 10, thus thereby facilitating the welding of the first heat dissipating assembly 10 to the inlet connector 40 and the outlet connector 50. The welding methods can include friction welding, diffusion welding, etc.

In the embodiment, the first protruding portion 171 and the second protruding portion 172 are portions of the first covering plate 17. The first groove 261 and the second groove 262 are formed on the surface of the second heat dissipating plate 26 facing the first heat dissipating assembly 10. The first protruding portion 171 and the second protruding portion 172 are defined on the second mounting portion 22. When the first heat dissipating assembly 10 and the second heat dissipating assembly 20 are assembled with each other, the first protruding portion 171 is placed in the first groove 261, and the second protruding portion 172 is placed in the second groove 262, thereby facilitating the assembly of the first heat dissipating assembly 10 and the second heat dissipating assembly 20. Additionally, the first protruding portion 171 is received in the first groove 261 and the second protruding portion 172 is received in the second groove 262, thereby facilitating an alignment of the first inlet hole 14 and the second inlet hole 24, as well as an alignment of the first outlet hole 15 and the second outlet hole 25.

The first accommodating groove 161 and the second accommodating groove 162 are defined on the surface of the first heat dissipating plate 16 and located on the first mounting portion 12. The first inlet hole 14 is connected to the first accommodating groove 161, and the first outlet hole 15 is connected to the second accommodating groove 162. When a plurality of first heat dissipating assembly 10 are assembled together, the first protruding portion 171 is received in the first accommodating groove 161, and the second protruding portion 172 is received in the second accommodating groove 162, facilitating the assembly of two adjacent first heat dissipating assemblies 10.

The radiator 100 can further include a first sealing member 71 and a second sealing member 72. The first sealing member 71 is disposed in the first groove 261. The second sealing member 72 is disposed in the second groove 262. The first sealing member 71 and the second sealing member 72 can fill a gap between the first covering plate 17 of the first heat dissipating assembly 10 and the second heat dissipating plate 26 of the second heat dissipating assembly 20, thereby preventing the leakage of liquid or gas. The first sealing member 71 and the second sealing member 72 can be made of rubber such as ethylene propylene diene monomer (EPDM) and nitrile rubber (NBR), which have good heat resistance, wear resistance, oil resistance, and adhesive strength. It is understood that sealing members can also be disposed between adjacent first heat dissipating assemblies 10.

The radiator 100 can further includes a plurality of fixing members 80. The fixing member 80 can detachably connect one first heat dissipating assembly 10 to the adjacent second heat dissipating assembly 20, thereby allowing the first heat dissipating assembly 10 to detachably connect to the second heat dissipating assemblies 20. The fixing member 80 can also detachably connect two adjacent first heat dissipating assemblies 10 to each other, thereby allowing the adjacent first heat dissipating assemblies 10 to detachably connect to each other and facilitating the adjustment of the number of first heat dissipating assemblies 10.

An avoidance groove 121 is defined on the first mounting portion 12 (referring to FIG. 3). When the fixing member 80 is fixed to the first heat dissipating assembly 10 and the adjacent second heat dissipating assembly 20, the fixing member 80 extends through the first heat dissipating assembly 10 and connects to the second heat dissipating assembly 20, with a portion of the fixing member 80 disposed in the avoidance groove 121. When the fixing member 80 is detachably connected two adjacent first heat dissipating assemblies 10, the fixing member 80 extends through one of the first heat dissipating assemblies 10 and connects to the other first heat dissipating assembly 10, with a portion of the fixing member 80 disposed in the avoidance groove 121. The avoidance groove 121 can reduce installation thickness of the radiator 100.

The radiator 100 can adjust the number of first heat dissipating assemblies 10. That is, the structure of the radiator 100 is flexible and can meet the needs of different usage scenarios, while also improving the space utilization rate of the radiator 100. An interior of the radiator 100 is a hollow structure, and the flow of the working fluid 240 in the radiator 100 can absorb the heat generated by the working member 230, thereby achieving heat dissipating and improving the heat dissipating efficiency of the radiator 100.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A radiator comprising:
at least one first heat dissipating assembly, each of the at least one first heat dissipating assembly comprising a first channel, a first inlet hole, and a first outlet hole, the first channel connected to the first inlet hole and the first outlet hole, and each of the first inlet hole and the first outlet hole extending through a corresponding first heat dissipating assembly of the at least one first heat dissipating assembly;
a second heat dissipating assembly detachably connected to one of the at least one first heat dissipating assembly, the second heat dissipating assembly comprising a second channel, a second inlet hole, and a second outlet hole, the second channel communicating with the second inlet hole and the second outlet hole, the second inlet hole communicating with the first inlet hole of the corresponding first heat dissipating assembly, and the second outlet hole communicating with the first outlet hole of the corresponding first heat dissipating assembly;
an inlet connector communicating with one of the first inlet hole; and
an outlet connector communicating with one of the first outlet hole.

2. The radiator of claim 1, wherein each of the at least one of the first heat dissipating assembly further comprising a first accommodating groove and a second accommodating groove, the first accommodating groove communicates with the first inlet hole of the corresponding first heat dissipating assembly, and the second accommodating groove communicates with the first outlet hole of the corresponding first heat dissipating assembly;
the inlet connector comprises a first connecting portion and a first protrusion, the first protrusion surrounds the first connecting portion, a portion of the first connecting portion is received in the first accommodating groove of one of the at least one first heat dissipating assembly, and the first protrusion abuts against the first heat dissipating assembly;
the outlet connector comprises a second connecting portion and a second protrusion, the second protrusion surrounds the second connecting portion, a portion of the second connecting portion is received in the second accommodating groove of one of the at least one first heat dissipating assembly, and the second protrusion abuts against the first heat dissipating assembly.

3. The radiator of claim 2, wherein the inlet connector further comprises at least one third protrusion, the at least one third protrusion surrounds the first connecting portion and is located on a side of the first protrusion opposite to the at least one first heat dissipating assembly;
the outlet connector further comprises at least one fourth protrusion, the at least one fourth protrusion surrounds the second connecting portion and is located on a side of the second protrusion opposite to the at least one first heat dissipating assembly.

4. The radiator of claim 1, wherein each of the at least one first heat dissipating assembly further comprises a first protruding portion and a second protruding portion, the first inlet hole extends through the first protruding portion, the first outlet hole extends through the second protruding portion;
the second heat dissipating assembly further comprises a first groove and a second groove, the second inlet hole communicates with the first groove, the second outlet hole communicates with the second groove;
the first protruding portion is received in the first groove, and the second protruding portion is received in the second groove.

5. The radiator of claim 4, further comprising a first sealing member and a second sealing member, wherein the first sealing member is disposed in the first groove, the second sealing member is disposed in the second groove, the first sealing member and the second sealing member are configured to fill a gap between the first heat dissipating assembly and the second heat dissipating assembly.

6. The radiator of claim 1, wherein each of the at least one of first heat dissipating assembly further comprises a first body portion and a first mounting portion, the first body portion is fixed to the first mounting portion of the corresponding first heat dissipating assembly, the first mounting portion is located on a side of the first body portion of the corresponding first heat dissipating assembly facing away from the second heat dissipating assembly, the second heat dissipating assembly further comprises a second body portion and a second mounting portion, the second mounting portion is disposed between the first body portion and the second body portion, and an installing space is formed between the first body portion and the second body portion.

7. The radiator of claim 6, further comprising a plurality of fixing members, wherein each of the plurality of fixing members is configured to detachably connect one of the at least one of first heat dissipating assembly to the second heat dissipating assembly;
the first mounting portion is provided with an avoidance groove, each of the plurality of fixing members extends through the corresponding first heat dissipating assembly and is detachably connected to the second heat dissipating assembly, and a portion of the fixing member is disposed in the avoidance groove.

8. The radiator of claim 1, wherein each of the at least one first heat dissipating assembly further comprises a first heat dissipating plate and a first covering plate, the first heat dissipating plate and the first covering plate of the corresponding first heat dissipating assembly cooperatively define a first channel, a first inlet hole extends through the first heat dissipating plate and the first covering plate of the corresponding first heat dissipating, and a first outlet hole further extends through the first heat dissipating plate and the first covering plate of the corresponding first heat dissipating;
the second heat dissipating assembly further comprise a second heat dissipating plate and a second covering plate, the second heat dissipating plate and the second covering plate cooperatively define the second channel, the second inlet hole extends through the second heat dissipating plate and communicates with the first inlet hole of the first heat dissipating assembly that is detachably connected to the second heat dissipating assembly, and the second outlet hole extends through the second heat dissipating plate and communicates with the first outlet hole of the corresponding first heat dissipating assembly.

9. The radiator of claim 1, further comprising a plurality of heat conducting sheets, wherein the plurality of heat conducting sheets is located on the at least one first heat dissipating assembly and the second heat dissipating assembly.

10. A terminal device comprising:
a radiator comprising:
at least one first heat dissipating assembly, each of the at least one first heat dissipating assembly comprising a first channel, a first inlet hole, and a first outlet hole, the first channel connected to the first inlet hole and the first outlet hole, and each of the first inlet hole and the first outlet hole extending through a corresponding first heat dissipating assembly of the at least one first heat dissipating assembly;
a second heat dissipating assembly detachably connected to one of the at least one first heat dissipating assembly, the second heat dissipating assembly comprising a second channel, a second inlet hole, and a second outlet hole, the second channel communicating with the second inlet hole and the second outlet hole, the second inlet hole communicating with the first inlet hole of the corresponding first heat dissipating assembly, and the second outlet hole communicating with the first outlet hole of the corresponding first heat dissipating assembly;
an inlet connector communicating with one of the first inlet hole; and
an outlet connector communicating with one of the first outlet hole;
an inlet tube communicating with the inlet connector;
an outlet tube communicating with the outlet connector;
a working member disposed between the at least one first heat dissipating assembly and the second heat dissipating assembly, or between two adjacent of the at least one first heat dissipating assembly; and
a working fluid configured to enter the radiator from the inlet tube, extending through the radiator, and discharged through the outlet tube.

11. The terminal device of claim 10, wherein each of the at least one of the first heat dissipating assembly further comprising a first accommodating groove and a second accommodating groove, the first accommodating groove communicates with the first inlet hole of the corresponding first heat dissipating assembly, and the second accommodating groove communicates with the first outlet hole of the corresponding first heat dissipating assembly;
the inlet connector comprises a first connecting portion and a first protrusion, the first protrusion surrounds the first connecting portion, a portion of the first connecting portion is received in the first accommodating groove of one of the at least one first heat dissipating assembly, and the first protrusion abuts against the first heat dissipating assembly;
the outlet connector comprises a second connecting portion and a second protrusion, the second protrusion surrounds the second connecting portion, a portion of the second connecting portion is received in the second accommodating groove of one of the at least one first heat dissipating assembly, and the second protrusion abuts against the first heat dissipating assembly.

12. The terminal device of claim 11, wherein he inlet connector further comprises at least one third protrusion, the at least one third protrusion surrounds the first connecting portion and is located on a side of the first protrusion opposite to the at least one first heat dissipating assembly;
the outlet connector further comprises at least one fourth protrusion, the at least one fourth protrusion surrounds the second connecting portion and is located on a side of the second protrusion opposite to the at least one first heat dissipating assembly.

13. The terminal device of claim 10, wherein each of the at least one first heat dissipating assembly further comprises a first protruding portion and a second protruding portion, the first inlet hole extends through the first protruding portion, the first outlet hole extends through the second protruding portion;
the second heat dissipating assembly further comprises a first groove and a second groove, the second inlet hole communicates with the first groove, the second outlet hole communicates with the second groove;
the first protruding portion is received in the first groove, and the second protruding portion is received in the second groove.

14. The terminal device of claim 13, wherein the radiator further comprises a first sealing member and a second sealing member, wherein the first sealing member is disposed in the first groove, the second sealing member is disposed in the second groove, the first sealing member and the second sealing member are configured to fill a gap between the first heat dissipating assembly and the second heat dissipating assembly.

15. The terminal device of claim 10, wherein each of the at least one of first heat dissipating assembly further comprises a first body portion and a first mounting portion, the first body portion is fixed to the first mounting portion of the corresponding first heat dissipating assembly, the first mounting portion is located on a side of the first body portion of the corresponding first heat dissipating assembly facing away from the second heat dissipating assembly, the second heat dissipating assembly further comprises a second body portion and a second mounting portion, the second mounting portion is disposed between the first body portion and the second body portion, and an installing space is formed between the first body portion and the second body portion.

16. The terminal device of claim 15, wherein the radiator further comprises
a plurality of fixing members, wherein each of the plurality of fixing members is configured to detachably connect one of the at least one of first heat dissipating assembly to the second heat dissipating assembly;
the first mounting portion is provided with an avoidance groove, each of the plurality of fixing members extends through the corresponding first heat dissipating assembly and is detachably connected to the second heat dissipating assembly, and a portion of the fixing member is disposed in the avoidance groove.

17. The terminal device of claim 10, wherein
each of the at least one first heat dissipating assembly further comprises a first heat dissipating plate and a first covering plate, the first heat dissipating plate and the first covering plate of the corresponding first heat dissipating assembly cooperatively define a first channel, a first inlet hole extends through the first heat dissipating plate and the first covering plate of the corresponding first heat dissipating, and a first outlet hole further extends through the first heat dissipating plate and the first covering plate of the corresponding first heat dissipating;
the second heat dissipating assembly further comprise a second heat dissipating plate and a second covering plate, the second heat dissipating plate and the second covering plate cooperatively define the second channel, the second inlet hole extends through the second heat dissipating plate and communicates with the first inlet hole of the first heat dissipating assembly that is detachably connected to the second heat dissipating assembly, and the second outlet hole extends through the second heat dissipating plate and communicates with the first outlet hole of the corresponding first heat dissipating assembly.

18. The terminal device of claim 10, wherein the radiator further comprises a plurality of heat conducting sheets, wherein the plurality of heat conducting sheets is located on the at least one first heat dissipating assembly and the second heat dissipating assembly.
